(19) United States
(12) Patent Application Publication
(10) Pub. No.: US 2010/0155753 A1
(43) Pub. Date: Jun. 24, 2010

(54) PHOSPHOR, LIGHT EMITTING DEVICE AND WHITE LIGHT EMITTING DIODE

(75) Inventors: Yuichiro Imanari, Tsukuba-shi (JP); Susumu Miyazaki, Toride-shi (JP); Kenji Toda, Niigata-shi (JP)

Correspondence Address: SUGHRUE MION, PLLC, 2100 PENNSYLVANIA AVENUE, N.W., SUITE 800, WASHINGTON, DC, 20037, US

(73) Assignee: Sumitomo Chemical Company, Limited, Chuo-ku, Tokyo (JP)

(21) Appl. No.: 11/815,130

(22) PCT Filed: Feb. 20, 2006
(86) PCT No.: PCT/JP06/03515

§ 371 Date: Sep. 12, 2007

(30) Foreign Application Priority Data
Feb. 23, 2005 (JP) 2005-046666
Feb. 23, 2005 (JP) 2005-046667

(51) Int. Cl. H01L 33/44; C09K 11/54; C09K 11/08; C09K 11/61

(52) U.S. Cl. 257/98; 252/301.6 R; 252/301.4 R; 252/301.4 H; 257/E33.061

(57) ABSTRACT

The present invention provides a phosphor, a lighting system and a white light emitting diode. The phosphor comprises a compound represented by the formula (1) and Eu as an activator. aM¹₂O.bM²O.cM³O₂ (1) wherein, in the formula (1), M¹ is at least one selected from the group consisting of Li, Na, K, Rb and Cs, M² is at least one selected from the group consisting of Ca, Sr, Ba, Mg and Zn, M³ is at least one selected from the group consisting of Si and Ge, 0.1≦a≦1.5, 0.8≦b≦1.2, 0.8≦a≦1.2, and when M¹ is Li, M³ is Si, and a=b=c=1, then M² is not Sr alone.

### TECHNICAL FIELD

The present invention relates to a phosphor, a lighting system and a light emitting diode. Specifically, the present invention relates to a phosphor that exhibits low dependence of emission intensity on temperature so as to have high heat stability, and to a lighting system and a light emitting diode which include such a phosphor.

### BACKGROUND ART

A phosphor is used in a lighting system whose excitation source is light ranging from ultraviolet to blue light (for example, a white light emitting diode (hereinafter, a light emitting diode will be referred to as an “LED”)), and known examples of phosphors for use in white LEDs include a compound represented by the formula Y₃Al₅O₁₂:Ce (JP 10-242513); and a compound represented by the formula (Ba_{1-x-y-z}SrₓCa_{y})₂SiO₄:Eu_{z}, and a compound represented by the formula Li₂SrSiO₄:Eu (WO 03/80763).

### DISCLOSURE OF THE INVENTION

The phosphors described in these publications are reduced in emission intensity when the temperature in the environment is high.

An object of the present invention is to provide a phosphor and a lighting system which have sufficient emission intensity and exhibit low dependence of emission intensity on temperature so as to have high heat stability. Another object of the present invention is to provide a white LED that exhibits low dependence of emission intensity on temperature so as to have high heat stability.

The present inventors conducted diligent studies in an attempt to solve the above problem, and have accomplished the present invention.

The present invention provides a phosphor I comprising a compound represented by the formula (1) and Eu as an activator.

aM¹₂O.bM²O.cM³O₂ (1)

wherein M¹ is at least one selected from the group consisting of Li, Na, K, Rb and Cs,

M² is at least one selected from the group consisting of Ca, Sr, Ba, Mg and Zn,

M³ is at least one selected from the group consisting of Si and Ge,

0.1≦a≦1.5,

0.8≦b≦1.2, and

0.8≦c≦1.2.

when M¹ is Li, M³ is Si, and a=b=c=1, then M² is not Sr alone.

Further, the present invention provides the phosphor I, comprising a compound represented by the formula (2).

M¹₂(M²₁₋ₓEuₓ)M³O₄ (2)

Wherein, in the formula (2), M¹ is at least one selected from the group consisting of Li, Na, K, Rb and Cs,

M² is one selected from the group consisting of Ca, Ba, Mg and Zn, or at least two selected from the group consisting of Ca, Sr, Ba, Mg and Zn,

M³ is at least one selected from the group consisting of Si and Ge, and

0<x<1.

The present invention provides a lighting system comprising the phosphor I and a light emitting device.

Furthermore, the present invention provides a white LED comprising a phosphor II containing a compound represented by the formula (3) and a light emitting diode to excite the phosphor.

M⁴₂(M⁵_{1-y}Euₓ)M⁶O₄ (3)

Wherein, in the formula (3), M⁴ is at least one selected from the group consisting of Li, Na, K, Rb and Cs,

M⁵ is at least one selected from the group consisting of Ca, Sr, Ba, Mg and Zn,

M⁶ is at least one selected from the group consisting of Si and Ge, and

0<x≦1.

### MODE FOR CARRYING OUT THE INVENTION

### Phosphor I

The phosphor I of the present invention includes a compound represented by the above formula (1) and europium (Eu) as an activator.

In the formula (1), M¹ is lithium (Li), sodium (Na), potassium (K), rubidium (Rb) or cesium (Cs). M¹ may be one element selected from the group consisting of these elements; combination of two elements such as combination of Li and Na, combination of Li and K, combination of Li and Rb, combination of Li and Cs, combination of Na and K, combination of Na and Rb, combination of Na and Cs, combination of K and Rb, combination of K and Cs, or combination of Rb and Cs; combination of three elements such as combination of Li, Na and K, combination of Li, Na and Rb, combination of Li, Na and Cs, combination of Li, K and Rb, combination of Li, K and Cs, combination of Li, Rb and Cs, combination of Na, K and Rb, combination of Na, K and Cs, or combination of K, Rb and Cs; combination of four elements such as Li, Na, K and Rb, combination of Li, Na, K and Cs, or combination of Na, K, Rb and Cs; or combination of five elements, i.e., Li, Na, K, Rb and Cs.

M² is calcium (Ca), strontium (Sr), barium (Ba), magnesium (Mg) or zinc (Zn). M² may be one element selected from the group consisting of these elements; combination of two elements such as combination of Ca and Sr, combination of Ca and Ba, combination of Ca and Mg, combination of Ca and Zn, combination of Sr and Ba, combination of Sr and Mg, combination of Sr and Zn, combination of Ba and Mg, or combination of Ba and Zn; combination of three elements such as combination of Ca, Sr and Ba, combination of Ca, Sr and Mg, combination of Ca, Sr and Zn, combination of Sr, Ba and Mg, combination of Sr, Ba and Zn, or combination of Ba, Mg and Zn; combination of four elements such as combination of Ca, Sr, Ba and Mg, combination of Ca, Sr, Ba and Zn, or combination of Ca, Ba, Mg and Zn; or combination of five elements, i.e., Ca, Sr, Ba, Mg and Zn, and is preferably single element such as Ca, Ba, Mg or Zn, combination of the above two elements, combination of the above three elements, combination of the above four elements, or combination of the above five elements.

M³ is silicon (Si) or germanium (Ge), and may be Si alone, Ge alone, or combination of Si and Ge.

a is 0.1 or more, preferably 0.8 or more, and is 1.5 or less, preferably 1.2 or less.

b is 0.8 or more, and is 1.2 or less.

c is 0.8 or more, and is 1.2 or less.

In the phosphor I, M² is not Sr alone when M¹=Li, M³=Si, and a=b=c=1 in the formula (1). In this case, M² is single element such as Ca, Ba, Mg or Zn; combination of the above two elements; combination of the above three elements; combination of the above four elements; or combination of the above five elements.

Further, the phosphor I preferably includes a compound represented by the formula (2). When the phosphor I, including the compound represented by the formula (2), is used for a white LED, the resultant white LED exhibits higher emission intensity.

M¹ in the formula (2) is the same as M¹ in the formula (1), preferably Li, Na, K or combination thereof, and more preferably Li.

M² in the formula (2) is the same as M² in the formula (1), preferably single element such as Ca, Ba, Mg or Zn, combination of the above two elements, combination of the above three elements, combination of the above four elements or combination of the above five elements, more preferably Ca alone, Sr alone or combination of Ca and Sr, and further preferably combination of Ca and Sr.

M³ in the formula (2) is the same as M³ in the formula (1), and is preferably Si.

x is more than 0, preferably 0.001 or more, and more preferably 0.01 or more, and is less than 1, preferably 0.5 or less, and more preferably 0.3 or less.

The phosphor I may further include, as an activator, an element other than Eu. Examples of the elements other than Eu include scandium (Sc), yttrium (Y), lanthanum (La), gadolinium (Gd), cerium (Ce), praseodymium (Pr), neodymium (Nd), samarium (Sm), terbium (Tb), dysprosium (Dy), holmium (Ho), erbium (Er), thulium (Tm), ytterbium (Yb), lutetium (Lu), manganese (Mn), and bismuth (Bi). The activator may either be single one of these elements or combination thereof.

Moreover, the phosphor I may further include halogen such as fluorine (F), chlorine (Cl), bromine (Br) or iodine (I). When the phosphor including halogen is used for a white LED, the resultant white LED exhibits higher emission intensity. The amount of the halogen is usually 10 ppm or more by weight, preferably 30 ppm or more by weight, and more preferably 50 ppm or more by weight, and is usually 10000 ppm or less by weight, and preferably 1000 ppm or less by weight based on the phosphor.

The phosphor I is suitably used for a white LED including a light emitting diode (e.g., an ultraviolet LED or a blue LED) as an excitation source. Furthermore, the phosphor may also be used for a vacuum ultraviolet excited lighting system such as PDP; an ultraviolet excited lighting system such as a backlight for liquid crystal display or three band fluorescent lamp; and an electron beam excited lighting system such as cathode ray tube (CRT) or field emission display (FED).

The phosphor I may be produced by calcining a mixture of metal compounds, which converts to the phosphor I by calcination.

Examples of the metal compounds include compounds of lithium, sodium, potassium, rubidium, cesium, calcium, strontium, barium, magnesium, zinc, silicon, germanium, scandium, yttrium, lanthanum, gadolinium, lutetium, cerium, praseodymium, neodymium, samarium, europium, terbium, dysprosium, holmium, erbium, thulium, ytterbium, manganese, and bismuth; for example, the metal compound may be an oxide or a compound, such as hydroxide, carbonate, nitrate, halide or oxalate, which may be decomposed and/or oxidized at high temperature to convert to an oxide.

The mixture may be prepared by weighing and mixing the metal compounds so as to satisfy the composition of the phosphor I. The mixing may be carried out using an apparatus such as ball mill, V-shaped mixer or agitator, for example. The mixing may either be carried out in a wet manner or in a dry manner.

When the compound represented by the formula Li₂(Sr_{0.88}Ca_{0.1}Eu_{0.02})SiO₄ is prepared, Li₂CO₃, SrCO₃, CaCO₃, Eu₂O₃ and SiO₂ may be weighed and mixed so as to allow the molar ratio of Li:Sr:Ca:Eu:Si to satisfy 2.0:0.88:0.1:0.02:1.0.

When the mixture contains a compound, such as hydroxide, carbonate, nitrate, halide or oxalate, which is decomposed and/or oxidized at high temperature to convert to an oxide, the mixture is preferably pre-calcined prior to calcination. The pre-calcination may be carried out under the condition that bound water of the hydroxide is removed or the hydroxide is converted to an oxide, and may usually be carried out at temperature lower than calcination temperature. Furthermore, the pre-calcined mixture may be pulverized.

The calcination temperature is usually 700° C. or more, preferably 800° C. or more, and more preferably 850° C. or more, and is usually 1400° C. or less, preferably 1200° C. or less, and more preferably 1100° C. or less. The calcination may be carried out under conditions of retention time of 1 to 100 hours, atmosphere of inert gas such as nitrogen or argon; oxidizing gas such as air, oxygen, oxygen-containing nitrogen, or oxygen-containing argon; or reducing gas such as hydrogen-containing nitrogen containing 0.1 to 10 percent of hydrogen by volume or hydrogen-containing argon containing 0.1 to 10 percent of hydrogen by volume. When the calcination is carried out under the reducing atmosphere, an appropriate amount of carbon may be added to a mixture of the metal compounds prior to the calcination. Due to the addition of carbon, the calcination is carried out under strong reducing atmosphere.

Furthermore, in order to improve the crystallinity of the phosphor I, an appropriate amount of flux may be added to a mixture of the metal compounds prior to the calcination. Examples of the flux include LiF, NaF, KF, LiCl, NaCl, KCl, Li₂CO₃, Na₂CO₃, K₂CO₃, NaHCO₃, NH₄Cl, and NH₄I. The calcination may be carried out twice or more.

The phosphor I may be pulverized, and the pulverization may be carried out using ball mill or jet mill. Furthermore, the phosphor I may be washed or classified.

### Lighting System

The lighting system of the present invention includes the above phosphor I, and usually includes the phosphor I and a light emitting device. The light emitting device may be one that emits light for exciting the phosphor, and may emit light with a wavelength of 200 nm to 550 nm. The light emitting device is, for example, ultraviolet LED, blue LED or the like, usually includes p electrode, p-type contact layer, emission layer, n-type contact layer, n electrode and so on, and has GaN, InᵢGa₁₋ᵢN (0<i<1), or InᵢAlⱼGa₁₋ᵢ₋ⱼN (0<i<1, 0<j<1, i+j<1) as the emission layer. The emission wavelength of the LED may be adjusted by changing the composition of the emission layer. The LED may be fabricated by the method disclosed in JP 6-177423 or JP 11-191638. Furthermore, the light emitting device may be a commercial device as long as it emits light for exciting the phosphor I to emit light. The lighting system may include other phosphor in addition to the phosphor I, and examples of the other phosphor include BaMgAl₁₀O₁₇:Eu; (Ba, Sr, Ca) (Al, Ga)₂S₄:Eu; BaMgAl₁₀O₁₇:Eu, Mn; BaAl₁₂O₁₉:Eu, Mn; (Ba, Sr, Ca) S:Eu, Mn; YBO₃: Ce, Tb; Y₂O₃:Eu; Y₂O₂S:Eu; YVO₄:Eu; (Ca, Sr) S:Eu; SrY₂O₄:Eu; Ca—Al—Si—O—N:Eu; and Li—(Ca, Mg)-Ln-Al—O—N:Eu [Ln represents a rare earth metal element other than Eu].

The lighting system may be fabricated, for example, by the method of covering the light emitting device with resin (e.g., transparent resin such as epoxy resin) and placing the phosphor I thereon (disclosed in JP 11-31845 and JP 2002-226846), or the method of mixing the phosphor I with resin (e.g., transparent resin such as epoxy resin, polycarbonate, or silicon rubber) and coating the light emitting device with the resultant resin in which the phosphor I is dispersed (disclosed in JP 5-152609) . In the phosphor I, the phosphor amount may be adjusted, or when two or more kinds of phosphors are used in combination, the amount ratio of the phosphor I and the other phosphor may be adjusted so as to obtain a desired emission color.

### White LED and Phosphor II

The white LED of the present invention includes a phosphor II containing a compound represented by the above formula (3) and a light emitting diode “LED”.

M⁴ in the above formula (3) is Li, Na, K, Rb or Cs. These elements may be used either alone or in combination. M⁵ is Ca, Sr, Ba, Mg or Zn. These elements may also be used either alone or in combination. M⁶ is Si alone, Ge alone, or combination of Si and Ge. y is more than 0, preferably 0.001 or more, and more preferably 0.01 or more, and is 1 or less, preferably 0.5 or less, and more preferably 0.3 or less.

The phosphor II may further contain, as an activator, an element other than Eu. Examples of the elements other than Eu include scandium (Sc), yttrium (Y), lanthanum (La), gadolinium (Gd), cerium (Ce), praseodymium (Pr), neodymium (Nd), samarium (Sm), terbium (Tb), dysprosium (Dy), holmium (Ho), erbium (Er), thulium (Tm), ytterbium (Yb), lutetium (Lu), manganese (Mn), and bismuth (Bi). The activator may either be single one of these elements or combination thereof.

The phosphor II may further contain halogen such as fluorine (F), chlorine (Cl), bromine (Br) and iodine (I). When the phosphor II containing halogen is used for a white LED, the resultant white LED exhibits higher emission intensity. The amount of the halogen is usually 10 ppm or more by weight, preferably 30 ppm or more by weight, and more preferably 50 ppm or more by weight, and is usually 10000 ppm or less by weight, and preferably 1000 ppm or less by weight based on the phosphor.

The phosphor II may be prepared by the same method as that for preparing the phosphor I except that the condition of weighing a mixture is changed. The phosphor II may be produced by calcining a mixture of metal compounds which is converted to the phosphor II by calcination.

Examples of the metal compounds include compounds of lithium, sodium, potassium, rubidium, cesium, calcium, strontium, barium, magnesium, zinc, silicon, germanium, scandium, yttrium, lanthanum, gadolinium, lutetium, cerium, praseodymium, neodymium, samarium, europium, terbium, dysprosium, holmium, erbium, thulium, ytterbium, manganese, and bismuth; for example, the metal compound may be an oxide or a compound, such as hydroxide, carbonate, nitrate, halide or oxalate, which may be decomposed and/or oxidized at high temperature to convert to an oxide.

The mixture may be prepared by weighing and mixing the metal compounds so as to satisfy the composition of the phosphor. The mixing may be carried out using an apparatus such as ball mill, V-shaped mixer or agitator. The mixing may either be carried out in a wet manner or in a dry manner.

When the compound represented by the formula Li₂(Sr_{0.98}Eu_{0.02})SiO₄ is prepared, Li₂CO₃, SrCO₃, Eu₂O₃ and SiO₂ may be weighed and mixed so as to allow the molar ratio of Li:Sr:Eu:Si to satisfy 2.0:0.98:0.02:1.0.

When the mixture contains a compound, such as hydroxide, carbonate, nitrate, halide or oxalate, which is decomposed and/or oxidized at high temperature to convert to an oxide, the mixture is preferably pre-calcined prior to calcination. The pre-calcination may be carried out under the condition that bound water of the hydroxide is removed or the hydroxide is converted to the oxide, and may usually be carried out at temperature lower than calcination temperature. Furthermore, the pre-calcined mixture may be pulverized.

The calcination may be carried out under conditions of temperature of 700° C. to 1600° C., retention time of 1 to 100 hours, atmosphere of inert gas such as nitrogen or argon; oxidizing gas such as air, oxygen, oxygen-containing nitrogen, or oxygen-containing argon; or reducing gas such as hydrogen-containing nitrogen containing 0.1 to 10 percent of hydrogen by volume or hydrogen-containing argon containing 0.1 to 10 percent of hydrogen by volume. When the calcination is carried out under reducing atmosphere, an appropriate amount of carbon may be added to a mixture of the metal compounds prior to the calcination. Due to the addition of carbon, the calcination is carried out under strong reducing atmosphere.

Furthermore, in order to improve the crystallinity of the phosphor II, an appropriate amount of flux may be added to a mixture of the metal compounds prior to the calcination. Examples of the flux include LiF, NaF, KF, LiCl, NaCl, KCl, Li₂CO₃, Na₂CO₃, K₂CO₃, NaHCO₃, NH₄Cl, and NH₄I. The calcination may be carried out twice or more.

The phosphor II may be pulverized, and the pulverization may be carried out using ball mill or jet mill. The phosphor II may be washed or classified.

The white LED may include other phosphor in addition to the phosphor II. The other phosphor is also excited by light from the LED to emit light.

When the LED is an ultraviolet LED for emitting light with a wavelength of 200 nm to 410 nm, examples of the other phosphor include: BaMgAl₁₀O₁₇:Eu; BaMgAl₁₀O₁₇:Eu, Mn; BaAl₁₂O₁₉:Eu, Mn; YBO₃:Ce, Tb; Y₂O₃:Eu; Y₂O₂S:Eu; YVO₄:Eu; SrY₂O₄:Eu; Ca—Al—Si—O—N: Eu; and Li—(Ca, Mg)-Ln-Al—O—N:Eu [Ln represents a rare earth metal element other than Eu]. When the LED is a blue LED for emitting light with a wavelength of 410 nm to 550 nm, examples of the other phosphor include: (Ba, Sr, Ca) (Al, Ga)₂S₄:Eu; (Ba, Sr, Ca) S:Eu, Mn; (Ca, Sr) S:Eu; Ca—Al—Si—O—N:Eu; and Li—(Ca, Mg)-Ln-Al—O—N:Eu [Ln represents a rare earth metal element other than Eu].

The LED emits light for exciting the phosphor II; for example, the LED is ultraviolet LED for emitting light with a wavelength of 200 nm to 410 nm or blue LED for emitting light with a wavelength of 410 nm to 550 nm, and is preferably blue LED. The LED may be fabricated by the method disclosed in JP 6-177423 or JP 11-191638. The LED usually includes p electrode, p-type contact layer, emission layer, n-type contact layer, n electrode and so on, and has, as the emission layer, semiconductor layer such as GaN, InᵢGa₁₋ᵢN (0<i<1), or InᵢAlⱼGa₁₋ᵢ₋ⱼN (0<i<1, 0<j<1, i+j<1). The emission wavelength of the LED may be adjusted by changing the composition of the emission layer. The LED may be a commercial device as long as it emits light for exciting the phosphor II.

The white LED may be fabricated, for example, by the method of mixing the phosphor II with resin (e.g., transparent resin such as epoxy resin, polycarbonate, or silicon rubber) and coating the blue LED with the resultant resin in which the phosphor II is dispersed (disclosed in JP 5-152609), or the method of covering the blue LED with resin (e.g., transparent resin such as epoxy resin) and placing the phosphor II thereon (disclosed in JP 11-31845 and JP 2002-226846) .

### EXAMPLES

The present invention is described in more detail by following Examples, which should not be construed as a limitation upon the scope of the present invention. The emission intensity of the phosphor is determined using a spectrofluorometer (“SPEX Fluorog-3” manufactured by Jobin Yvon Inc.) under the following conditions.

### Conditions:

Excitation light source: 450W xenon lamp

Scan interval: 1 nm

Excitation spectrum measurement range: 250 to 500 nm

Fluorescence spectrum measurement range: 380 to 780 nm

### Reference 1

Yttrium oxide (manufactured by Shin-Etsu Chemical Co., Ltd.: purity 99.99%), gadolinium oxide (manufactured by Shin-Etsu Chemical Co., Ltd.: purity 99.99%), cerium oxide (manufactured by Shin-Etsu Chemical Co., Ltd.: purity 99.99%), and aluminum oxide (manufactured by Sumitomo Chemical Co., Ltd.: purity 99.99%) were weighed in a manner such that the molar ratio of Y:Gd:Ce:Al was 1.71:1.2:0.09:5.0. 10 parts by weight of the mixture and 150 parts by weight of isopropyl alcohol were put into a wet ball mill and mixed for 4 hours to obtain a slurry. The slurry was dried at 70° C. using an evaporator to obtain a mixture of the metal compounds, and the mixture was calcined at 1600° C. for 24 hours under air atmosphere and then cooled down (at a cooling rate of 5° C./min) to a room temperature (25° C.) to obtain a phosphor 1. The composition of the phosphor 1 was shown in Table 1.

The emission intensity of the phosphor 1 irradiated with light having a wavelength of 460 nm at a room temperature (25° C.) was defined as 100, and the emission intensities (relative values) of the phosphor 1 irradiated with light having a wavelength of 460 nm at 50° C., 75° C., 100° C. and 120° C. were determined. The results thereof were shown in Table 2.

### Example 1

Lithium carbonate (manufactured by Kanto Chemical Co., Inc.: purity 99%), strontium carbonate (manufactured by Sakai Chemical Industry Co., Ltd.: purity 99% or more), calcium carbonate (manufactured by Ube Material Industries, Ltd.: purity 99.9%), europium oxide (manufactured by Shin-Etsu Chemical Co., Ltd.: purity 99.99%), silicon dioxide (manufactured by Nippon Aerosil Co., Ltd.: purity 99.99%) were weighed in a manner such that the molar ratio of Li:Sr:Ca:Eu:Si was 2.0:0.88:0.1:0.02:1.0. 10 parts by weight of the mixture and 150 parts by weight of isopropyl alcohol were put into a wet ball mill, mixed for 4 hours to obtain a slurry. The slurry was dried at 70° C. using an evaporator to obtain a mixture of the metal compound. The mixture was calcined at 900° C. for 12 hours under air atmosphere, and then cooled down (at a cooling rate of 5° C./min) to a room temperature (25° C.). Subsequently, the resultant was pulverized using an agate mortar, and calcined at 900° C. for 12 hours under N₂ atmosphere containing 2% by volume of H₂, and then cooled down (at a cooling rate of 5° C./min) to a room temperature to obtain a phosphor 2. The composition of the phosphor 2 was shown in Table 1, and the emission intensities thereof were shown in Table 2.

### Example 2

Except that lithium carbonate (manufactured by Kanto Chemical Co., Inc.: purity 99%), strontium carbonate (manufactured by Sakai Chemical Industry Co., Ltd.: purity 99% or more), barium carbonate (manufactured by Nippon Chemical Industrial Co., Ltd.: purity 99% or more), europium oxide (manufactured by Shin-Etsu Chemical Co., Ltd.: purity 99.99%), and silicon dioxide (manufactured by Nippon Aerosil Co., Ltd.: purity 99.99%) were used as materials and that the molar ratio of Li:Sr:Ba:Eu:Si was 2.0:0.88:0.1:0.02:1.0, the same operations as Example 1 were carried out to obtain a phosphor 3. The composition of the phosphor 3 was shown in Table 1, and the emission intensities thereof were shown in Table 2.

### Example 3

Lithium carbonate (manufactured by Kanto Chemical Co., Inc.: purity 99%), strontium carbonate (manufactured by Sakai Chemical Industry Co., Ltd.: purity 99% or more), calcium carbonate (manufactured by Ube Material Industries, Ltd.: purity 99.9%), europium oxide (manufactured by Shin-Etsu Chemical Co., Ltd.: purity 99.99%), silicon dioxide (manufactured by Nippon Aerosil Co., Ltd.: purity 99.99%), and ammonium chloride (manufactured by Wako Pure Chemical Industries, Ltd.: purity 99%) were weighed in a manner such that the molar ratio of Li:Sr:Ca:Eu:Si:Cl was 2.0:0.88:0.1:0.02:1.0:0.05. 10 parts by weight of the mixture and 150 parts by weight of isopropyl alcohol were put into a wet ball mill and mixed for 4 hours to obtain a slurry. The slurry was dried at 70° C. using an evaporator to obtain a metal compound mixture. The mixture was calcined at 900° C. for 12 hours under air atmosphere, and then cooled down to a room temperature. Subsequently, the resultant was pulverized using an agate mortar, and calcined at 900° C. for 12 hours under N₂ atmosphere containing 2% by volume of H₂ᵢ and then cooled down to a room temperature to obtain a phosphor 4. The composition of the phosphor 4 was shown in Table 1, and the emission intensities thereof were shown in Table 2.

### Example 4

Except that lithium carbonate (manufactured by Kanto Chemical Co., Inc.: purity 99%), strontium carbonate (manufactured by Sakai Chemical Industry Co., Ltd.: purity 99% or more), calcium carbonate (manufactured by Ube Material Industries, Ltd.: purity 99.9%), europium oxide (manufactured by Shin-Etsu Chemical Co., Ltd.: purity 99.99%), silicon dioxide (manufactured by Nippon Aerosil Co., Ltd.: purity 99.99%), and lithium fluoride (manufactured by Kojundo Chemical Laboratory Co., Ltd.: purity 99% or more) were used as materials, the molar ratio of Li:Sr:Ca:Eu:Si:F was 2.0:0.88:0.1:0.02:1.0:0.05, and that the molar ratio of the lithium carbonate Li₂CO₃ and the lithium fluoride LiF was 0.975:0.05, the same operations as Example 3 were carried out to obtain a phosphor 5. The composition of the phosphor 5 was shown in Table 1, and the emission intensities thereof were shown in Table 2.

### Example 5

Except that lithium carbonate (manufactured by Kanto Chemical Co., Inc.: purity 99%), strontium carbonate (manufactured by Sakai Chemical Industry Co., Ltd.: purity 99% or more), europium oxide (manufactured by Shin-Etsu Chemical Co., Ltd.: purity 99.99%), and silicon dioxide (manufactured by Nippon Aerosil Co., Ltd.: purity 99.99%) were used as materials and that the molar ratio of Li:Sr:Eu:Si was 2.0:0.98:0.02:1.0, the same operations as Example 1 were carried out to obtain a phosphor 6. The composition of the phosphor 6 was shown in Table 1.

### Test 1

The phosphor 2, phosphor 3, phosphor 4, phosphor 5 and phosphor 6 were irradiated with light having a wavelength of 460 nm, respectively. The emission intensities thereof were determined. The results were shown in Table 3. The results were illustrated as relative values with respect to the emission intensity of the phosphor 6, the value of which was defined as 100.

### Example 6

Lithium carbonate (manufactured by Kanto Chemical Co., Inc.: purity 99%), strontium carbonate (manufactured by Sakai Chemical Industry Co., Ltd.: purity 99% or more), europium oxide (manufactured by Shin-Etsu Chemical Co., Ltd.: purity 99.99%), silicon dioxide (manufactured by Nippon Aerosil Co., Ltd.: purity 99.99%), and ammonium chloride (manufactured by Wako Pure Chemical Industries, Ltd.: purity 99%) were weighed in a manner such that the molar ratio of Li:Sr:Eu:Si:Cl was 2.0:0.98:0.02:1.0:0.05. 10 parts by weight of the mixture and 150 parts by weight of isopropyl alcohol were put into a wet ball mill and mixed for 4 hours to obtain a slurry. The slurry was dried using an evaporator to obtain a metal compound mixture. The mixture was calcined at 900° C. for 12 hours under air atmosphere, and cooled down to a room temperature. The resultant was pulverized using an agate mortar, and calcined at 900° C. for 12 hours under N₂ atmosphere containing 2% by volume of H₂, and then cooled down to a room temperature to obtain a phosphor 7. The composition of the phosphor 7 was shown in Table 1, and the emission intensities thereof were shown in Table 2.

### Test 2

The phosphor 6, phosphor 7 and phosphor 4 were irradiated with light having a wavelength of 460 nm, respectively. The emission intensities thereof were determined. The results were shown in Table 4. The results were illustrated as relative values with respect to the emission intensity of the phosphor 6, the value of which was defined as 100.

### Example 1 of Fabricating for Lighting System (White LED)

A lighting system was fabricated by applying the phosphor 4 to a blue LED having an In_{0.3}Ga_{0.7}N emission layer so that the blue LED was surrounded with the phosphor 4. The lighting system emits white light due to the color mixture of the light from the blue LED and the light emitted from the phosphor 4 which was excited under irradiation of the blue light from the LED.

### INDUSTRIAL APPLICABILITY

According to the present invention, provided are a phosphor, a lighting system and a white LED which exhibit sufficient emission intensity and reduce the emission intensity degradation according to temperature increase.

TABLE 1
Phosphor Composition

| | | Phosphor Composition | Halogen Content |
|---|---|---|---|
| Ref. 1 | Phosphor | (Y_{0.57}Gd_{0.4}Ce_{0.03})₃Al₅O₁₂ | |
| | 1 | | |
| Example | Phosphor | Li₂(Sr_{0.88}Ca_{0.1}Eu_{0.02})SiO₄ | Fluorine: 8 ppm |
| 1 | 2 | | Chlorine: 15 ppm |
| | | | Bromine: 2 ppm |
| | | | Iodine: 4 ppm |
| Example | Phosphor | Li₂(Sr_{0.88}Ba_{0.1}Eu_{0.02})SiO₄ | Fluorine: 7 ppm |
| 2 | 3 | | Chlorine: 11 ppm |
| | | | Bromine: 4 ppm |
| | | | Iodine: 6 ppm |
| Example | Phosphor | Li₂(Sr_{0.88}Ca_{0.1}Eu_{0.02})SiO₄ | Fluorine: 7 ppm |
| 3 | 4 | | Chlorine: 130 ppm |
| | | | Bromine: 4 ppm |
| | | | Iodine: 6 ppm |
| Example | Phosphor | Li₂(Sr_{0.88}Ca_{0.1}Eu_{0.02})SiO₄ | Fluorine: 270 ppm |
| 4 | 5 | | Chlorine: 11 ppm |
| | | | Bromine: 4 ppm |
| | | | Iodine: 6 ppm |
| Example | Phosphor | Li₂(Sr_{0.98}Eu_{0.02})SiO₄ | Fluorine: 5 ppm |
| 5 | 6 | | Chlorine: 7 ppm |
| | | | Bromine: 4 ppm |
| | | | Iodine: 3 ppm |
| Example | Phosphor | Li₂(Sr_{0.98}Eu_{0.02})SiO₄ | Fluorine: 9 ppm |
| 6 | 7 | | Chlorine: 100 ppm |
| | | | Bromine: 3 ppm |
| | | | Iodine: 4 ppm |

TABLE 2
Temperature Dependence on Emission Intensity of Phosphor

| | | Emission Intensity | | | | |
|---|---|---|---|---|---|---|
| | | 25° C. | 50° C. | 75° C. | 100° C. | 120° C. |
| Ref. 1 | Phosphor 1 | 100 | 95 | 88 | 81 | 78 |
| Example 1 | Phosphor 2 | 100 | 100 | 100 | 99 | 97 |
| Example 2 | Phosphor 3 | 100 | 99 | 98 | 97 | 95 |
| Example 3 | Phosphor 4 | 100 | 100 | 100 | 99 | 97 |
| Example 4 | Phosphor 5 | 100 | 101 | 100 | 99 | 97 |
| Example 5 | Phosphor 6 | 100 | 100 | 98 | 98 | 95 |
| Example 6 | Phosphor 7 | 100 | 101 | 100 | 100 | 97 |

* The emission intensities of the respective phosphors at 50° C., 75° C., 100° C. and 120° C. were shown as relative values with respect to the emission intensity of each phosphor irradiated with light having a wavelength of 460 nm at 25° C., which was defined as 100.

TABLE 3
Emission Intensity Of Phosphor

| | | Emission Intensity |
|---|---|---|
| Example 1 | Phosphor 2 | 110 |
| Example 2 | Phosphor 3 | 107 |
| Example 3 | Phosphor 4 | 134 |
| Example 4 | Phosphor 5 | 121 |
| Example 5 | Phosphor 6 | 100 |

* The emission intensities were results of irradiation of light with a wavelength of 460 nm at 25° C. The emission intensities of the phosphors 2 to 5 were shown as relative values with respect to the emission intensity of the phosphor 6, which was defined as 100.

TABLE 4
Emission Intensity Of Phosphor

| | | Chlorine | Emission |
|---|---|---|---|
| | | Content | Intensity |
| Example 5 | Phosphor 6 | 7 ppm | 100 |
| Example 6 | Phosphor 7 | 100 ppm | 110 |

* The emission intensities were results of irradiation of light with a wavelength of 460 nm at 25° C. The emission intensities of the phosphors 7 and 4 were shown as relative values with respect to the emission intensity of the phosphor 6, which was defined as 100.

1. A phosphor comprising a compound represented by the formula (1) and Eu as an activator.
aM¹₂O.bM²O.cM³O₂ (1)
wherein, in the formula (1),
M¹ is at least one selected from the group consisting of Li, Na, K, Rb and Cs,
M² is at least one selected from the group consisting of Ca, Sr, Ba, Mg and Zn,
M³ is at least one selected from the group consisting of Si and Ge,
0.1≦a≦1.5,
0.8≦b≦1.2,
0.8≦c≦1.2, and
when M¹ is Li, M³ is Si, and a=b=c=1, then M² is not Sr alone.

2. The phosphor according to claim 1, wherein M² is one selected from the group consisting of Ca, Ba, Mg and Zn, or at least two selected from the group consisting of Ca, Sr, Ba, Mg and Zn.

3. The phosphor according to claim 1, comprising a compound represented by the formula (2).
M¹₂(M²₁₋ₓEuₓ)M³O₄ (2)
wherein, in the formula (2),
M¹ is at least one selected from the group consisting of Li, Na, K, Rb and Cs,
M² is one selected from the group consisting of Ca, Ba, Mg and Zn, or at least two selected from the group consisting of Ca, Sr, Ba, Mg and Zn,
M³ is at least one selected from the group consisting of Si and Ge, and
0<x<1.

4. The phosphor according to claim 1, wherein the phosphor further comprises at least one selected from the group consisting of Sc, Y, La, Gd, Ce, Pr, Nd, Sm, Tb, Dy, Ho, Er, Tm, Yb, Lu, Mn and Bi as an activator.

5. The phosphor according to claim 1, wherein the phosphor further comprises at least one halogen selected from the group consisting of F, Cl, Br and I.

6. The phosphor according to claim 5, wherein the amount of the halogen is 10 to 10000 ppm by weight based on the phosphor.

7. A lighting system comprising the phosphor according to claim 1.

8. The lighting system according to claim 7, wherein the lighting system further comprises a light emitting device to excite the phosphor.

9. The lighting system according to claim 8, wherein the light emitting device emits light with a wavelength of 200 nm to 550 nm.

10. The lighting system according to claim 9, wherein the light emitting device is a light emitting diode.

11. A white light emitting diode comprising a phosphor containing a compound represented by the formula (3) and a light emitting diode to excite the phosphor.
M⁴₂(M⁵_{1-y}Euₓ)M⁶O₄ (3)
wherein, in the formula (3),
M⁴ is at least one selected from the group consisting of Li, Na, K, Rb and Cs,
M⁵ is at least one selected from the group consisting of Ca, Sr, Ba, Mg and Zn,
M⁶ is at least one selected from the group consisting of Si and Ge, and
0<x≦1.

12. The white light emitting diode according to claim 11, wherein the phosphor further comprises at least one selected from the group consisting of Sc, Y, La, Gd, Ce, Pr, Nd, Sm, Tb, Dy, Ho, Er, Tm, Yb, Lu, Mn and Bi as an activator,

13. The white light emitting diode according to claim 11, wherein the phosphor further comprises at least one halogen selected from the group consisting of F, Cl, Br and I.

14. The white light emitting diode according to claim 11, wherein the light emitting diode to excite the phosphor is an ultraviolet LED or a blue LED.

15. The white light emitting diode according to claim 14, wherein the light emitting diode to excite the phosphor is a blue LED.

16. A phosphor comprising a compound represented by the formula (3) and at least one halogen selected from the group consisting of F, Cl, Br and I.
M⁴₂(M⁵_{1-y}Euₓ)M⁶O₄ (3)
wherein, in the formula (3),
M⁴ is at least one selected from the group consisting of Li, Na, K, Rb and Cs,
M⁵ is at least one selected from the group consisting of Ca, Sr, Ba, Mg and Zn,
M⁶ is at least one selected from the group consisting of Si and Ge, and
0<x≦1.

17. The phosphor according to claim 16, wherein the amount of the halogen is 10 to 10000 ppm by weight based on the phosphor.
